(19) United States
(12) Patent Application Publication
(10) Pub. No.: US 2023/0260883 A1
(43) Pub. Date: Aug. 17, 2023

(54) INTERPOSER, CIRCUIT DEVICE, METHOD OF MANUFACTURING INTERPOSER, AND METHOD OF MANUFACTURING CIRCUIT DEVICE

(71) Applicant: SONY SEMICONDUCTOR SOLUTIONS CORPORATION, KANAGAWA (JP)

(72) Inventor: MASAHIKO AIBA, KANAGAWA (JP)

(21) Appl. No.: 18/003,095

(22) PCT Filed: May 20, 2021
(86) PCT No.: PCT/JP2021/019123

§ 371 Date: Dec. 22, 2022

(30) Foreign Application Priority Data
Jul. 2, 2020 (JP) 2020-115206

(51) Int. Cl. H01L 23/498; H01L 23/00; H01L 23/42; H01L 21/48

(52) U.S. Cl. CPC H01L 23/49827; H01L 21/486; H01L 23/42; H01L 23/562; H01L 24/32; H01L 24/48; H01L 24/73; H01L 2224/32225; H01L 2224/48227; H01L 2224/73265; H01L 2924/3512

(57) ABSTRACT

The occurrence of cracks and the like are prevented due to thermal stress associated with Joule heat generated by a semiconductor chip in vias for electrical connection with the back surface, arranged around the semiconductor chip. A substrate 11 with a semiconductor chip 20A mounted face-up on its surface includes a plurality of heat dissipation vias 15 in an area corresponding to a semiconductor chip mounting section. The substrate 11 is covered with an insulating layer 12 made from an insulating resin with low thermal conductivity on a surface exclusive of an opening for a wire 40A and openings 12B for the heat dissipation vias 15. A back surface of the semiconductor chip 20A is bonded to the semiconductor chip mounting section of the substrate 11 with an adhesive layer 50 made from a resin with high thermal conductivity, and is connected through the adhesive layer 50 to the openings 12B for the plurality of heat dissipation vias 15 filled with a resin with high thermal conductivity provided in the semiconductor chip mounting section of the substrate 11.

### TECHNICAL FIELD

The present technology relates to an interposer, a circuit device, a method of manufacturing the interposer, and a method of manufacturing the circuit device.

### BACKGROUND ART

System in package (SiP) modules have hitherto been developed that enable a large-scale system to be implemented in a single package as a technology for various electronic products such as mobile phones, digital cameras, and tuner products. This SiP technology, in which a plurality of ICs or packages are stacked, makes it possible to increase memory capacity and combine functions, resulting in providing a variety of miniaturized, lightweight, and high functionality electric products.

Such SiP modules and the like can use existing manufacturing equipment, and thus those having a face-up structure that enable low-cost manufacturing are in widespread use. Furthermore, an interposer is also known in which vias are provided through the front and back surfaces of a circuit board to achieve conduction between a semiconductor chip such as an LSI on the front surface and a ground on the back surface, which is utilized as one of the high integration technologies.

In recent years, there has been a need for further miniaturization of the SiP structure, and accordingly, the development of effective heat dissipation means for high-density mounting is also required. Under such circumstances, for example, for a compact, high-density mounting SiP, an interposer with a heat dissipation via (thermal via) structure has been proposed (see PTL 1 and PTL 2, for example).

PTL 1 and PTL 2 describe structures in which, in order to improve the heat dissipation of a circuit board and reduce the deterioration of reliability caused by the heat generated from the circuit elements, the heat (Joule heat) from an LSI chip is radiated to the outside through metal vias (for example, metal protrusions and thermal vias) for direct connection to the back surface of the LSI chip (PTL 1) and vias for connection to the back surface of the LSI chip via a conductive metal (for example, island and bonding agent) (PTL 2).

In addition, a technology has been proposed in which a heat dissipation means that occupies a large area is provided to increase the mounting efficiency of metal parts (for example, thermal vias) that serve as the heat dissipation means and increase the heat dissipation efficiency (see PTL 3, for example).

Furthermore, for the purpose of relaxing the thermal stress to the outside of a semiconductor chip mounting section, a structure has been proposed in which a concave portion made of a metal such as copper is provided, and the concave portion is filled with a cushioning material made from thermosetting resin with a lower Young’s modulus than that of the metal of the concave portion (see PTL 4).

### CITATION LIST

### Patent Literature

PTL 1] JP 2007-324330A
PTL 2] JP 2006-339596A
PTL 3] JP 2007-096083A
PTL 4] JP 2006-310783A

### SUMMARY

### Technical Problem

In the structures disclosed in PTL 1 and PTL 2 mentioned above, for example, metal heat dissipation vias are arranged on part of the bottom surface of a conductive layer connected to the ends of signal lines around the LSI chip. However, when the heat generated by Joule heat generated by the LSI chip is conducted to the heat dissipation vias, cracks may occur in parts of the heat dissipation vias due to the thermal expansion of the heat dissipation vias, resulting in a problem of poor electrical connection reliability and the like.

Even in the structure disclosed in PTL 3, connection wires such as signal lines between LSI elements and a wiring layer are performed in the vicinity of heat dissipation vias arranged around a semiconductor element. Accordingly, the heat dissipation vias through which Joule heat generated by the LSI elements is transferred may be thermally expanded due to the Joule heat, so that cracks may occur in the heat dissipation vias; and thermal stress may occur due to the Joule heat transferred also through the signal lines, so that a variety of troubles may occur.

In the structure disclosed in PTL 4, the concave portion being formed results in a substantially reduced mounting area on the circuit board, causing a problem of reducing the mounting density.

The present technology aims to prevent the occurrence of cracks and the like, due to thermal stress associated with Joule heat generated by a semiconductor element such as an LSI chip, in heat dissipation vias (thermal vias) and vias for electrical connection with the back surface, arranged around the semiconductor element.

### Solution to Problem

An interposer according to the present technology includes: a wiring substrate that is formed of an insulating resin; a wiring via that is provided for electrical connection between both surfaces of the wiring substrate; a plurality of heat dissipation vias that are provided fitting in a region of a chip mounting section where a semiconductor chip is mounted on the wiring substrate; and an insulating layer that covers a surface of the wiring substrate exclusive of an opening of the wiring via and openings of the heat dissipation vias with an insulating resin with low thermal conductivity.

In another aspect of the interposer according to the present technology, the heat dissipation vias each have a circular opening with a same diameter and are arranged in a grid pattern at equal intervals.

In another aspect of the interposer according to the present technology, the insulating resin with low thermal conductivity is a solder resist, and the resin with high thermal conductivity is Ag paste.

A circuit device according to the present technology includes: a wiring substrate that is formed of an insulating resin; a wiring via that is provided for electrical connection between both surfaces of the wiring substrate; a plurality of heat dissipation vias that are provided in a region of a chip mounting section where a semiconductor chip is mounted on the wiring substrate; an insulating layer that covers a surface of the wiring substrate exclusive of an opening of the wiring via and openings of the heat dissipation vias with an insulating resin with low thermal conductivity; and an adhesive layer that is formed of a resin with high thermal conductivity so that a back surface of the semiconductor chip is adhesively fixed to the chip mounting section, and thermally connects the semiconductor chip to the heat dissipation vias.

In another aspect of the circuit device according to the present technology, the heat dissipation vias each have a circular shape with a same opening diameter and are arranged in a grid pattern at equal intervals.

In another aspect of the circuit device according to the present technology, the insulating resin with low thermal conductivity is a solder resist, and the resin with high thermal conductivity is Ag paste.

A method of manufacturing an interposer according to the present technology includes the steps of: forming, on a wiring substrate that is formed of an insulating resin, a wiring via for electrical connection between both surfaces of the wiring substrate and a plurality of heat dissipation vias that each have an opening in a region of a chip mounting section where the semiconductor chip is mounted; and forming an insulating layer to cover a surface of the wiring substrate exclusive of an opening of the wiring via and the openings of the heat dissipation vias with an insulating resin with low thermal conductivity.

In another aspect of the method of manufacturing the interposer according to the present technology, the step of forming the heat dissipation vias includes forming each of the heat dissipation vias into a circular shape with a same opening diameter, and forming the heat dissipation vias in a grid pattern at equal intervals.

In another aspect of the method of manufacturing the interposer according to the present technology, the step of forming the insulating layer includes forming the insulating layer by using a solder resist as the insulating resin with low thermal conductivity, and the step of forming an adhesive layer includes using Ag paste as the resin with high thermal conductivity.

A method of manufacturing a circuit device according to the present technology includes the steps of: forming, on a wiring substrate that is formed of an insulating resin, a wiring via for electrical connection between both surfaces of the wiring substrate and a plurality of heat dissipation vias that each have an opening in a region of a chip mounting section where the semiconductor chip is mounted; forming an insulating layer to cover a surface of the wiring substrate exclusive of an opening of the wiring via and the openings of the heat dissipation vias with an insulating resin with low thermal conductivity; forming an adhesive layer for bonding and fixing a back surface of the semiconductor chip to the chip mounting section with a resin with high thermal conductivity to thermally connect the semiconductor chip and the heat dissipation vias; and bonding and fixing the semiconductor chip to the adhesive layer face-up.

In another aspect of the method of manufacturing the circuit device according to the present technology, the step of forming the heat dissipation vias includes forming each of the heat dissipation vias into an opening circular shape with a same diameter, and forming the heat dissipation vias in a grid pattern at equal intervals.

In another aspect of the method of manufacturing the circuit device according to the present technology, the step of forming the insulating layer includes forming the insulating layer by using a solder resist as the insulating resin with low thermal conductivity, and the step of forming an adhesive layer includes using Ag paste as the resin with high thermal conductivity.

Another method of manufacturing a circuit device according to the present technology includes the steps of: forming, on a wiring substrate that is formed of an insulating resin, a wiring via for electrical connection between both surfaces of the wiring substrate and a plurality of heat dissipation vias that each have an opening in a region of a chip mounting section where the semiconductor chip is mounted; forming an insulating layer to cover a surface of the wiring substrate exclusive of an opening of the wiring via and the openings of the heat dissipation vias with an insulating resin with low thermal conductivity; coating a resin with high thermal conductivity on a back surface of the semiconductor chip; and forming an adhesive layer by bonding and fixing the semiconductor chip with the resin with high thermal conductivity coated to the chip mounting section on the wiring substrate side face-up to thermally connect the semiconductor chip and the heat dissipation vias.

In another aspect of the other method of manufacturing the circuit device according to the present technology, the step of forming the heat dissipation vias includes forming each of the heat dissipation vias into an opening circular shape with a same diameter, and forming the heat dissipation vias in a grid pattern at equal intervals.

In another aspect of the other method of manufacturing the circuit device according to the present technology, the step of forming the insulating layer includes forming the insulating layer by using a solder resist as the insulating resin with low thermal conductivity, and the step of forming an adhesive layer includes using Ag paste as the resin with high thermal conductivity.

### BRIEF DESCRIPTION OF DRAWINGS

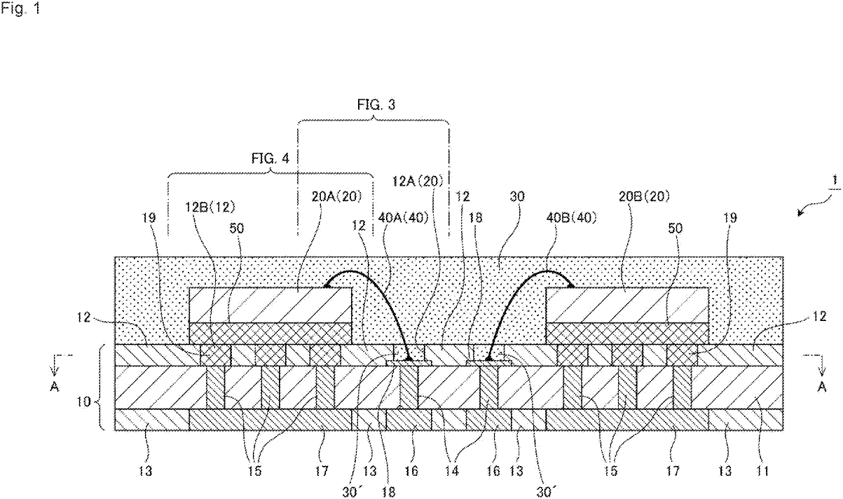

### [FIG. 1]

FIG. 1 is a cross-sectional view illustrating a structure of a circuit device including an interposer according to a first embodiment of the present technology.

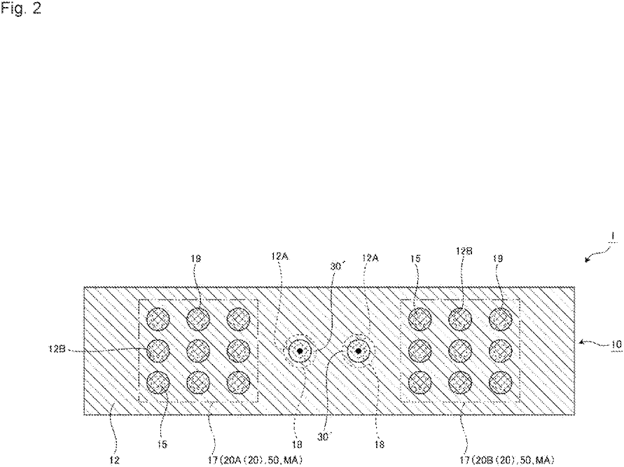

### [FIG. 2]

FIG. 2 is a cross-sectional view taken along arrow-line A-A in the circuit device according to the first embodiment of the present technology.

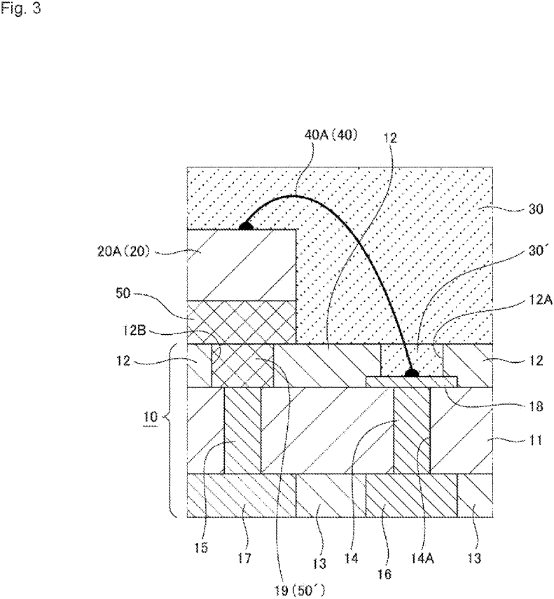

### [FIG. 3]

FIG. 3 is an enlarged cross-sectional view illustrating a structure near a wiring via, according to the first embodiment of the present technology.

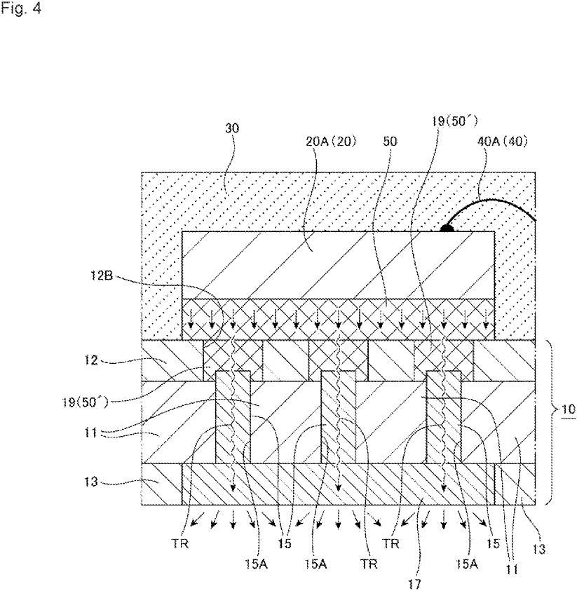

### [FIG. 4]

FIG. 4 is an enlarged cross-sectional view illustrating a structure near heat dissipation vias according to the first embodiment of the present technology.

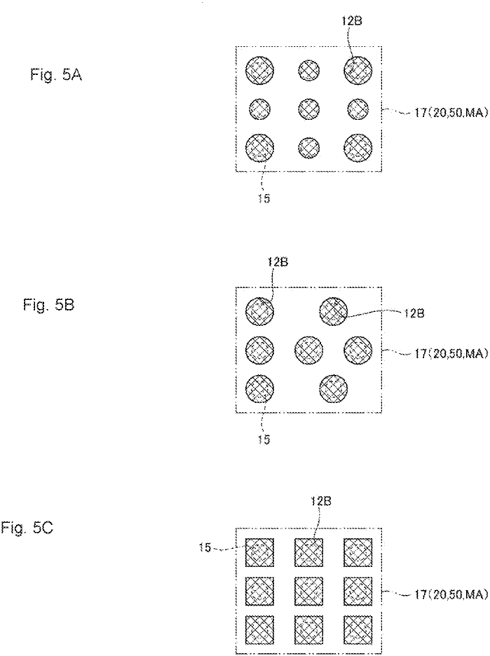

### [FIG. 5]

FIG. 5 includes explanatory diagrams illustrating other aspects of the heat dissipation vias according to the first embodiment of the present technology, where (A) is an aspect of a combination of openings with different inner diameters of an insulating layer; (B) is an aspect of arrangement of openings that is not in a grid pattern; and (C) is an aspect of openings with a square shape.

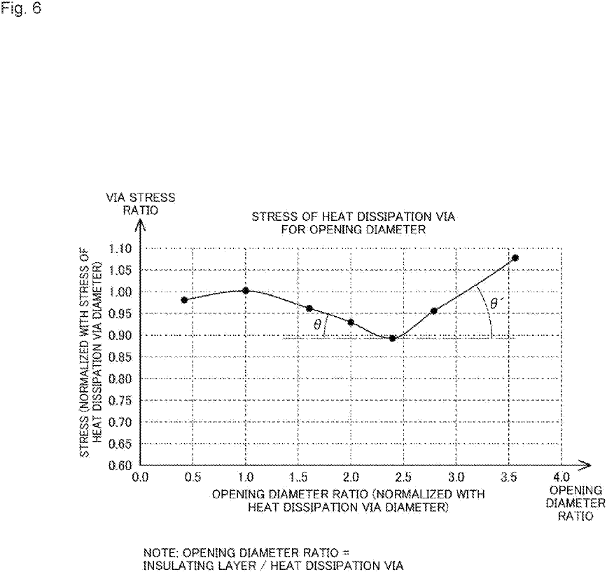

### [FIG. 6]

FIG. 6 is a graph showing the correlation between the opening diameter ratio between the inner diameter of the opening and the outer diameter of the heat dissipation via and the stress of the heat dissipation via, according to the first embodiment of the present technology.

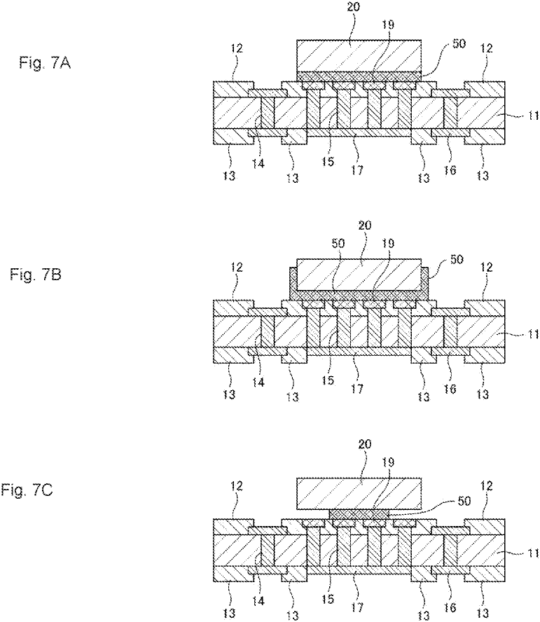

### [FIG. 7]

FIG. 7 illustrates (A) a main part of the circuit device according to the first embodiment of the present technology, and (B) and (C) modification examples of the main part.

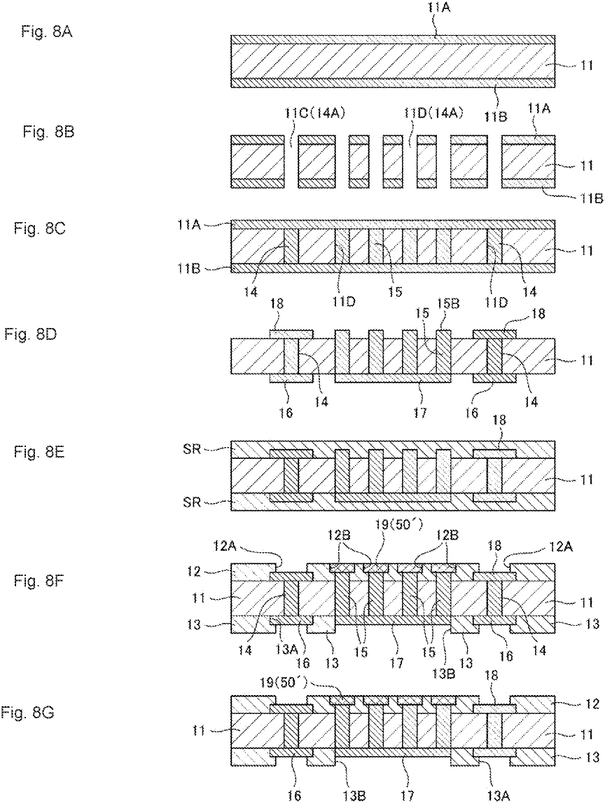

### [FIG. 8]

FIG. 8 illustrates (A) to (G) process diagrams of the first half of a process of manufacturing a circuit device including an interposer according to a third embodiment of the present technology.

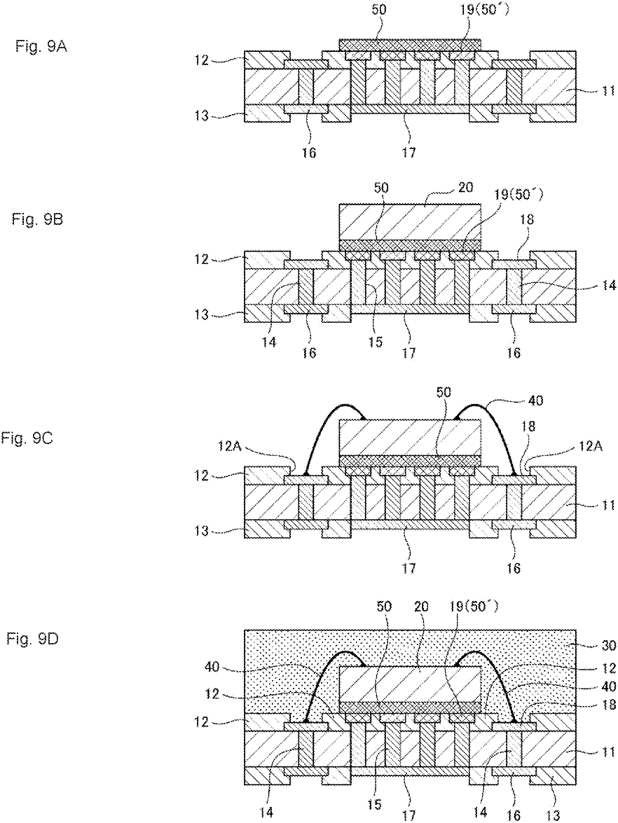

### [FIG. 9]

FIG. 9 illustrates (H) to (K) process diagrams of the second half of the process of manufacturing the circuit device including the interposer according to the third embodiment of the present technology.

### DESCRIPTION OF EMBODIMENTS

In an interposer of the present technology, a resin with high thermal conductivity is provided over the entire bottom surface of a chip, and a plurality of heat dissipation vias are provided to be connected to the bottom surface of the resin with high thermal conductivity, so that the local concentration of Joule heat generated by the semiconductor chip in the heat dissipation vias is dispersed and avoided, in order to prevent the occurrence of cracks in the heat dissipation vias due to the concentration of thermal stress associated with Joule heat generated from a semiconductor element.

Modes for carrying out the present technology (hereinafter referred to as embodiments) will be described below with reference to the drawings. The description of embodiments will be made in the following order.
1. Configuration Example of Circuit Device Including Interposer According to First Embodiment
2. Example of Method of Manufacturing Circuit Device Including Interposer According to Second Embodiment
3. Experimental Example Regarding Stress of Heat Dissipation Vias in Circuit Device Including Interposer According to Third Embodiment

### 1. Configuration Example of Circuit Device Including Interposer According to First Embodiment

A configuration example of a circuit device 1 including an interposer 10 according to a first embodiment of the present technology will be described with reference to FIGS. 1 to 4.

The circuit device 1 of the present embodiment includes the interposer 10, semiconductor chips 20 mounted on the interposer 10, a mold resin portion 30, a resin of which seals the semiconductor chips 20 (20A, 20B) from above, wires 40 (40A, 40B), and an adhesive layer 50 with a high thermal conductivity [W/m·K].

### [Configuration of Interposer]

The interposer 10 includes a wiring substrate 11 formed of an insulating resin or the like (hereinafter, simply referred to as “substrate 11”), insulating layers 12 and 13 formed on the top and bottom surfaces of the substrate 11, respectively, vias 14 for electrical connection between the top and bottom surfaces of the substrate 11 (hereinafter referred to as the “wiring vias 14”), heat dissipation vias 15, wiring terminals 16, and ground terminals 17.

The substrate 11 is formed of a core material obtained by slicing a wafer formed of silicon resin, epoxy resin, or the like into a thin plate with a predetermined thickness, and then forming conductive film layers such as copper foil on the top and bottom surfaces of the thin plate. Formed in or on the substrate 11 are the insulating layers 12 and 13, the wiring vias 14, the heat dissipation vias 15, conductive layers including terminals, electrodes, and lands for wiring in various patterns of shape (hereinafter referred to as the “wiring terminals 16”), terminals 17 for grounding formed with a wide conductive layer (hereinafter referred to as the “ground terminals 17”), and the like. The substrate 11 also has chip mounting sections where the respective semiconductor chips 20 are mounted across the insulating layer 12 and a filling layer 19 which will be described later (hereinafter referred to as the “chip mounting section (MA)”).

The insulating layers 12 and 13 are made from a solder resist with a required thickness and formed on the top and bottom surfaces of the substrate 11, respectively, into a predetermined pattern. As illustrated in FIG. 2, the insulating layers 12 and 13 have openings 12A and 12B, which are circular windows, at portions corresponding to the wiring vias 14 for connection with the wires 40 and the heat dissipation vias 15, respectively.

The above-described solder resist is made from a material with a lower thermal conductivity [W/m·K] than that of the adhesive layer 50 which will be described later and an adhesive such as Ag paste with a high thermal conductivity [W/m·K], which forms the filling portion 19 in each opening 12B provided in the insulating layer 12. Accordingly, the adhesive layer 50 and the filling portion 19 being provided cause the heat (Joule heat) from the semiconductor chip 20 to be transferred to the insulating layer 12 where the heat is to be accumulated, and thus prevent the occurrence of cracks at any position of the substrate 11 due to that heat.

In order to be electrically connected to the wiring terminals 16 made from copper foil or the like formed in a predetermined pattern on the back surface of the substrate 11, the wiring vias 14 are formed with a metal with high electrical conductivity embedded in via holes 14A for wiring.

As illustrated in FIG. 3, on the top surface of the substrate 11, which is the top surface of the wiring via 14, conductive layers (hereinafter referred to as “pattern wires 18”) including terminals, lands, electrodes, and the like which are formed in a predetermined pattern with copper foil or the like is provided for electrical conduction with the semiconductor chip 20. Further, above the pattern wire 18 and directly above the via hole 14A for the wiring via 14, the above-described opening 12A is formed with the surrounding insulating layer 12 removed to open a window.

A leading end of the wire 40 (such as a signal line) formed of Au wire (gold wire) or the like drawn out from the semiconductor chip 20 is connected to the pattern wire 18 by soldering or the like to make an electrical connection. A part of the mold resin portion 30 (referred to as a “filled resin portion 30”′) enters and fills the opening 12A of the insulating layer 12 during resin molding, but the details will be described later.

The heat dissipation vias 15 prevent the occurrence of cracks in the wiring via 14 due to the heat (Joule heat) generated from the semiconductor chip 20 being accumulated. In particular, the semiconductor chip 20 of the present disclosure has a face-up structure, and thus, for example, in the present embodiment, the entire bottom surface (back surface) of the semiconductor chip 20, on which pads (electrodes) for connection with the outside and the like are not formed, is used to cause the heat to be transferred from the bottom surface to the ground terminal 17 on the bottom surface of the substrate 11 to dissipate the heat. As illustrated in (C) of FIG. 7, which will be described later, a configuration may be employed in which a part of the bottom surface of the semiconductor chip 20 is bonded to the adhesive layer 50.

Each heat dissipation via 15 is formed of a metal material with high thermal conductivity (for example, Cu) by, for example, electroless plating so that the heat dissipation via 15 functions as a heat conduction route (hereinafter referred to as a “thermal route (TR)”) to be transferred heat generated by the semiconductor chip 20 to the ground terminal 17. In the case of the present embodiment, as illustrated in FIG. 2, a large number of perfect circles having the same radius are arranged in a grid pattern at equal intervals.

As illustrated in FIG. 4, the above-described openings 12B communicating with the via holes 15A for the heat dissipation vias 15 are formed in portions of the insulating layer 12 on the top surface of the substrate 11, which correspond to the portions where the heat dissipation vias 15 are formed. Each opening 12B is filled with Ag paste or the like with high thermal conductivity, which is the same material as that of the adhesive layer 50, to form the filling portion 19. With such a configuration, a thermal route (TR) from the semiconductor chip 20 is formed between the adhesive layer 50 and the ground terminal 17 through the filling portion 19 with high thermal conductivity in the opening 12B and through the heat dissipation via 15, so that an efficient heat dissipation effect can be exhibited.

As described above, the same material as the adhesive used for the adhesive layer 50 can be used for the filling portions 19, and the use of the same adhesive makes it possible to manufacture the adhesive layer 50 and the filling portions 19 at the same time. Thus, it is possible to reduce the manufacturing costs of the circuit device 1 by reducing the number of man-hours.

The requirements for the filling portions 19 to be satisfied, in addition to the above-mentioned high thermal conductivity, preferably include:
1) A coefficient of linear expansion not being significantly different from that of the material (solder resist in the present embodiment) used for the insulating layer 12; and
2) A longitudinal elastic modulus (Young’s modulus E) [N/m²] being lower than that of the metal material of the heat dissipation vias 15 because of the structure in which the bottom surface of each filling portion 19 is physically integrated with the top surface of the corresponding heat dissipation via 15.

The openings 12B formed in the insulating layer 12 may be arranged such that the openings 12B have different outer diameters as illustrated in (A) of FIG. 5, may be arranged such that the openings 12B have the same diameter in various arrangements instead of a grid pattern as illustrated in (B) of FIG. 5, or may be arranged such that the openings 12B each have a rectangular outer shape as illustrated in (C) of FIG. 5. The point is that any arrangement can be employed as long as it achieves the highest heat conduction efficiency, and the arrangement is not limited to the present disclosure.

The outer diameter ratio of the above-described opening 12B is set such that the outer diameter of the opening 12B is within three times or about three times the outer diameter of the heat dissipation via 15 as illustrated in FIG. 6, but the details will be described later. The reason why it is set to be within three times or about three times is that it is aimed to relax the stress associated with heat, stress may increase due to the difference in coefficient of linear expansion between an adhesive 50′, which is a resin that fills the opening 12B, and the insulating layer 12 formed of a solder resist, and such an increased stress is required to be reduced as much as possible.

The wiring terminal 16 is formed in a predetermined pattern with a conductive metal film such as copper foil on the back surface of the substrate 11. When the heat (Joule heat) transferred from the semiconductor chip 20 side through the wire 40 formed of an Au wire or the like is transferred to the connection terminal 16 formed from a conductive metal film such as copper foil in a predetermined pattern through the wiring via 14 with high electrical conductivity, it is expected that the heat is also dissipated from the connection terminal 16.

The ground terminal 17 occupies a larger area than the wiring terminal 16, so that the heat dissipation effect is also large accordingly. In the present embodiment, in order to effectively utilize this large heat dissipation effect to effectively release the heat generated by the semiconductor chip 20, the region where the ground terminal 17 is to be formed is designed to be on the bottom surface of the substrate 11 and at the position corresponding to the chip mounting section (MA) on the top surface of the substrate 11.

With such a configuration, the length of the thermal route (TR) is kept to the shortest length, and the heat is directly and efficiently dissipated to the outside of the substrate 11. Specifically, in the present embodiment, a thermal route (TR) is formed to transfer the heat generated by the semiconductor chip 20 from the back surface of the semiconductor chip 20 to the ground terminal 17 through the adhesive layer 50, the adhesive 50′, and the heat dissipation via 15, as described above.

### [Upper Configuration of Interposer]

Mounted on the top of the interposer 10 having the above configuration are the semiconductor chips 20, the mold resin portion 30, a thermosetting resin of which seals the semiconductor chips 20 (20A, 20B) and the like to protect them from above, the wires 40 (40A, 40B) using Au wire or the like, and the above-mentioned adhesive layer 50 with a high thermal conductivity [W/m·K], which form the circuit device 1.

Next, the semiconductor chips 20 mounted on the interposer 10, the mold resin portion 30, the resin of which seals the semiconductor chips 20 (20A, 20B) from above, the wires 40 (40A, 40B), the adhesive layer 50 with a high thermal conductivity (W/m·K), and the like will be described.

The semiconductor chips 20 (20A, 20B) are attached to the substrate 11 by a so-called face-up method, in which their surface (top surface) side with pads (electrodes) for wiring and the like mounted faces upward. Each semiconductor chip 20 is of a type of chip without pads (electrodes) for wiring mounted on its back surface (bottom surface).

Accordingly, in the present embodiment, in the mounting of the semiconductor chip 20 on the substrate 11, the entire back surface (bottom surface) of the semiconductor chip 20 is mounted in a “fully bonded” state using an adhesive with high thermal conductivity. Such mounting of the semiconductor chip 20 and the using of the adhesive with high thermal conductivity make it possible to efficiently guide (release) the heat (such as Joule heat) generated by the semiconductor chip 20 from the entire back surface of the semiconductor chip 20 to the substrate 11 side.

The wires 40 (40A, 40B) electrically connect the electrodes (pads) and the like of the semiconductor chips 20 to the top surfaces of the wiring vias 14 and the like by using a wire material (for example, Au wire) with high electrical conductivity, a wire bonder, and the like to make the electrical conduction between them.

As described above, the adhesive layer 50 is formed over the entire back surface (bottom surface) of the semiconductor chip 20 mounted by the face-up method and uses a material with high thermal conductivity, so that the heat generated by the semiconductor chip 20 can be transferred. As a result, a thermal route (TR) is formed that guides the heat to the ground terminal 17 through the filling portion 19 and the heat dissipation via 15 that are physically in direct contact with each other on the back surface of the adhesive layer 50.

Aspects of mounting the adhesive layer 50 may include, in addition to an aspect of bonding of the present embodiment illustrated in (A) of FIG. 7, for example, a configuration in which the adhesive layer 50 partially covers the outer sides of the semiconductor chip 20 as illustrated in (B) of FIG. 7, and a configuration in which the adhesive layer 50 is formed only on a central portion where heat tends to be concentrated as illustrated in (C) of FIG. 7, rather than on the entire back surface (bottom surface) of the semiconductor chip 20.

### [Functions and Effects of First Embodiment]

According to the circuit device 1 having the configuration as described above according to the present embodiment, attention is focused on the large area of the back surface (bottom surface) of the semiconductor chip 20, and the adhesive layer 50 using a material with high thermal conductivity is formed on the entire back surface (bottom surface) of the semiconductor chip 20 mounted face-up in order to efficiently and effectively dissipate the heat. In addition, the shortest thermal routes (TR) (see FIG. 4) connecting the back surface of the semiconductor chip 20 and the ground terminal 17 are formed so that the heat (Joule heat) generated by the semiconductor chip 20 is guided to the ground terminal 17 having a wide-area shape through the adhesive layer 50, the filling portions 19, and the heat dissipation vias 15.

Therefore, the heat generated by the semiconductor chip 20 is efficiently and effectively released to the ground terminal 17, so that the thermal stress associated with the heat generated by the semiconductor chip 20 acts on the wiring via 14 and the like to effectively prevent the occurrence of cracks and the like. In particular, it is possible to improve quality such as connection reliability for the semiconductor chip that generates a large amount of heat.

Since an effective heat generation effect is obtained by forming such a thermal route (TR) directly under the semiconductor chip 20, it is not necessary to form heat dissipation vias up to the periphery of the region where the semiconductor chip 20 is mounted. Therefore, the effectively use of the peripheral region of the semiconductor chip 20 makes it possible to arrange the semiconductor chips and connection wires at high density, resulting in the reduced size of the circuit device.

According to the present embodiment, for the semiconductor chip 20 mounted face-up on the top surface of the interposer 10, the thermal routes (TR) are formed between the back surface (bottom surface) portion of the semiconductor chip 20 and the plurality of heat dissipation vias 15 through the adhesive layer 50, which is a resin with high thermal conductivity, to provide a thermally conductive connection. Therefore, the Joule heat generated by the semiconductor chip 20 is dispersed without concentrating on a single heat dissipation via 15. This makes it possible to prevent the occurrence of cracks due to stress concentration on the heat dissipation via 15.

In the insulating layer 12 on the top surface of the substrate 11, the plurality of filling portions 19 filled with a resin with high thermal conductivity are provided in the plurality of openings 12B for the heat dissipation vias 15, which are opened in the area of the chip mounting section (MA). Therefore, these filling portions 19 and the insulating layer 12 with low thermal conductivity which surrounds the filling portions 19 function as thermal stress buffers, which relaxes the concentration of thermal stress around the heat dissipation vias 15, so that it is unnecessary to provide heat dissipation vias around the semiconductor chip 20. Accordingly, a large area for wiring vias can be secured around the semiconductor chip by the size corresponding to the area unnecessary for heat dissipation vias, which leads to an increase in the density of semiconductor chips to be mounted.

The circuit device 1 of the present embodiment has a structure in which the semiconductor chip 20 is stacked on the interposer 10, but may have a configuration in which a similar circuit device is further stacked below the interposer via an appropriate metal plate or the like.

### 2. Method of Manufacturing Interposer and Circuit Device According to Second Embodiment

Next, a method of manufacturing an interposer 10′ and a circuit device 1′ according to a second embodiment of the present disclosure will be described with reference to FIGS. 8 and 9. The interposer 10′ and the circuit device 1′ manufactured in the present embodiment differs from the interposer 10 and the circuit device 1 of the first embodiment in that an upper end portion of each heat dissipation via 15 slightly protrudes above the top surface of the substrate 11, and each connection terminal 16 and the ground terminal 17 are inside the bottom surface of the insulating layer 13.

The method of manufacturing the interposer 10 and the circuit device 1 of the present embodiment includes first step S1 to eleventh step S11.

In first step S1, as illustrated in (A) of FIG. 8, a core material is formed from a wafer or the like; the core material is composed of: a substrate 11 formed of an insulating material such as silicon or epoxy resin; and a top metal layer 11A and a bottom metal layer 11B which are each made from copper foil and formed on the top and bottom surfaces of the substrate 11, respectively.

Second step S2 includes, as illustrated in (B) of FIG. 8, the followings:

1) A photoresist, which is a photosensitive resin, is coated on each of both surfaces of the core material by using a technique such as photolithography (coating step).

2) After that, the resist is exposed using a mask formed in a predetermined wiring pattern (exposure step).

3) A latent image to be visualized, formed by the exposure, is developed with a developer (development step). As a result, a desired photoresist pattern to be visualized is revealed.

4) The entire surface of the substrate 11 including the transferred resist pattern (exposed portion or non-exposed portion) is immersed in an etchant. As a result, for example, for a positive type of resist, the copper foil portion exclusive of the resist pattern is dissolved and removed (resist removal step). Dissolving and removing the copper foil portion exclusive of the resist portion coated on the pattern area corresponding to the exposed portion with the etchant makes it possible to form only the copper foil portion of the pattern portion. As a result, the copper foil portion of the predetermined pattern area is formed as the corresponding one of the top metal layer 11A and the bottom metal layer 11B.

5) In this way, via holes 11C (indicated by numeral 14A in FIG. 3) and holes 11D (indicated by numeral 15 in FIG. 4) for forming wiring vias 14 and heat dissipation vias 15 are formed at predetermined positions.

In third step S3, as illustrated in (C) of FIG. 8, the holes 11C and 11D of the substrate 11 are subjected to plating (for example, electroless plating) with a metal such as copper with high electrical conductivity and high thermal conductivity so that the holes are connected to the metal layers 11A and 11B on the top and bottom surfaces. The metal plated in the holes 11C serves as the wiring vias 14, and the metal plated in the holes 11D serves as the heat dissipation vias 15.

In fourth step S4, as illustrated in (D) of FIG. 8, conductive layers (wiring vias 14, wiring terminals 16, and pattern wires 18), which provides wiring connections by predetermined patterning, and parts of the heat dissipation means (heat dissipation vias 15 and ground terminal 17 are formed on the top and bottom metal layers 11A and 11B. The method of forming the conductive layers and the heat dissipation means in the case of the present embodiment includes processes of: coating a photoresist, exposing the resist by using masks each having a predetermined pattern, developing the resist with a developer, removing the resist, and the like, to form the conductive layers and the like, as in the case of second step S2.

As a result, on the top surface of the substrate 11, conductive layers (the pattern wires 18) integrated with the wiring vias 14 formed in the holes 11C and metal protruding portions 15B (hereinafter referred to as “heat dissipation protrusions 15B”) (serving as heat dissipation means) integrated with the heat dissipation vias 15 formed in the holes 11D are formed. On the other hand, on the bottom surface of the substrate 11, the wiring terminals 16, which are conductive layers, are formed integrally with the wiring vias 14, and the ground terminals 17, which are conductive layers, are formed integrally with the heat dissipation vias 15.

In fifth step S5, as illustrated in (E) of FIG. 8, a solder resist SR, which is an insulating resin with low thermal conductivity, is coated with a predetermined thickness to cover the pattern wires 18, the wiring terminals 16, and the ground terminal 17, which are conductive layers on the top and bottom surfaces, and the heat dissipation protrusions 15B, which are heat dissipation means on the top surface. The solder resist SR is later removed in unnecessary portions to form insulating layers 12 and 13 on the top and bottom surfaces of the substrate 11.

In sixth step S6, as illustrated in (F) of FIG. 8, processes of: exposing the solder resists SR by using masks each having a predetermined pattern, developing the solder resist SR with a developer, and removing unnecessary portions of the solder resist, and the like are performed, and as a result, the necessary portions of the solder resist corresponding to the predetermined patterns remain so that they are the insulating layers 12 and 13 to be formed.

By this sixth step S6, the portions corresponding to the top surfaces of the wiring vias 14 are removed by predetermined diameters from the solder resist SR on the top surface of the substrate 11 to form circular openings 12A, and a plurality of portions corresponding to the top surfaces of the heat dissipation vias 15 are removed by predetermined diameters to form openings 12B.

Similarly, by this sixth step S6, the portions corresponding to the bottom surfaces of the wiring vias 14 are removed by predetermined diameters from the solder resist SR on the bottom surface of the substrate 11 to form circular openings 13A, and portions corresponding to the bottom surfaces of the heat dissipation vias 15 are removed by predetermined diameters to form openings 13B.

As illustrated in FIG. 3, each opening 12A is a spatial space for the wire 40A to be inserted by a wire bonder in wire bonding in order to serve as a portion to be connected to a leading end of the wire 40A (40) connected to the semiconductor chip 20.

As illustrated in FIG. 4, each opening 12B is for releasing the heat generated by the semiconductor chip 20 and relaxing thermal stress. Therefore, the opening 12B forms part of a thermal route that transfers the heat generated by the semiconductor chip 20 to the ground terminal 17. In other words, it serves as a space for forming a filling layer 19 with high thermal conductivity by using the same material at the same timing as an adhesive layer 50 to be formed in the post-process.

As described above, if the size of the opening 12B is excessively large compared to the outer diameter of the heat dissipation via 15, a difference in linear expansion coefficient between the resin with high thermal conductivity (Ag paste in the present embodiment) of the filling layer 19 formed by filling the opening 12B and the resin with low thermal conductivity (solder resist) serving as the insulating layer 12 may cause an increase in stress.

In order to avoid this, the opening 12B is formed within three times the outer diameter of the heat dissipation via 15. Similarly as illustrated in FIG. 5, the shape of the opening 12B is formed in a circle (for example, perfect circle), but is not particularly limited to the circle, and may be polygonal (for example, square). However, the opening 12B preferably has a circular shape, which has little local change of form, in order to avoid or relax the occurrence of local concentration of stress.

On the other hand, the openings 13A and 13B on the bottom surface of the substrate 11 in the case of the present embodiment have no particular use for their open spaces. However, for example, in the case where many circuit devices like the present embodiment are stacked, the openings 13A and 13B can be used for electrical connection (multilayer wiring) between adjacent circuit devices and for forming thermal routes for heat dissipation.

In seventh step S7, as illustrated in (G) of FIG. 8, an appropriate resin with high thermal conductivity is used as a filling material to fill the spaces of the openings 12B formed for stress relaxation, so that the resin filling the openings 12B forms filling layers 19. As already described in the first embodiment, this filling material preferably satisfies the following requirements:
1) A high thermal conductivity, as described above;
2) A coefficient of linear expansion not being significantly different from that of the material (solder resist in the present embodiment) used for the insulating layer 12; and
3) A longitudinal elastic modulus (Young’s modulus E) [N/m²] being lower than that of the metal material of the heat dissipation vias 15 because of the structure in which the bottom surface of each filling layers 19 is physically integrated with the top surface of the corresponding heat dissipation via 15.

Examples of materials to be used for such a filling layer 19 include a thermally conductive paste such as silver paste similar to that used in the first embodiment, and a thermally conductive film such as a die attach film (CDAF: Conductive Die Attach Film). The same material with high thermal conductivity as that used for the adhesive layer 50 in the next process is used in this process, so that seventh step S7, which is this process, and eighth step S8, which is the next process, can be performed simultaneously. Thus, it is possible to reduce the costs by reducing the number of man-hours.

In eighth step S8, as illustrated in (H) of FIG. 9, an appropriate adhesive with high thermal conductivity is coated on a predetermined region to form the adhesive layer 50 so as to cover the filling layers 19 on the top surface of the substrate 11. In this case, as portions on which the adhesive is to be coated, the adhesive is coated not only on the filling layers 19 but also on the top surface of the substrate 11 between the filling layers 19, that is, on portions of the insulating layer 12 formed of a solder resist.

In ninth step S9, as illustrated in (I) of FIG. 9, the semiconductor chip 20 is mounted face-up and fixed on the adhesive layer 50 so as to cover the adhesive layer 50 formed in eighth step S8.

In the case of the present embodiment, to form the adhesive layer 50, an adhesive is coated on the portion corresponding to the entire predetermined area including the filling layers 19, which is the chip mounting section (MA), on the top surface of the substrate 11, which covers the entire back surface (bottom surface) of the semiconductor chip 20. The entire back surface (bottom surface) of the semiconductor chip 20 is bonded and fixed to the top of the adhesive layer 50 in a fully bonded state.

In the present technology, the bonding interface of the semiconductor chip 20 when the semiconductor chip 20 is fixed to the insulating layer 12 and the filling layers 19 through the adhesive layer 50 is not particularly limited to the entire surface of the semiconductor chip 20. Aspects of the bonding may include, in addition to an aspect of the first embodiment illustrated in (A) of FIG. 7, a configuration in which the adhesive layer 50 partially covers the outer sides of the semiconductor chip 20 as illustrated in (B) of FIG. 7, and a configuration in which the adhesive layer 50 is formed only on a central portion where heat tends to be concentrated as illustrated in (C) of FIG. 7, rather than on the entire back surface (bottom surface) of the semiconductor chip 20.

In the present embodiment, an adhesive is first coated on a predetermined area (chip mounting section (MA)) on the top surface of the substrate 11 (eighth step S8), and then the semiconductor chip 20 is mounted on this area (ninth step S9). However, the processes may be performed in the following order: an adhesive is first coated on the back surface (bottom surface) of the semiconductor chip 20 and then the semiconductor chip 20 is bonded to the top surface side of the substrate 11.

In tenth step S10, as illustrated in (J) of FIG. 9, the wires 40 such as Au wires are connected between the pads (electrodes) of the semiconductor chip 20 and the pattern wires (conductive layers) 18 on the wiring vias 14 by wire bonding with a wire bonder.

In eleventh step S11, as illustrated in (K) of FIG. 9, a mold resin portion 30 is formed by resin molding using a thermosetting resin or the like so as to cover the semiconductor chip 20. During this resin molding, part of the resin enters the opening 12A above the pattern wire 18, and the opening 12A is filled with the resin to form a filled resin portion 30′, thereby protecting the pattern wire portion 18 from the outside as well as the semiconductor chip 20 and the insulating layer 12. Thus, the interposer 10 and the circuit device 1 are completed.

### [Effects of Second Embodiment]

Thus, according to the present embodiment, as described above, the same material with high thermal conductivity as that used for the adhesive layer 50 is used as a filling material for filling the spaces of the openings 12B, so that seventh step S7 and eighth step S8 can be performed simultaneously, and thus, it is possible to reduce the costs by reducing the number of man-hours.

According to the manufacturing method of the present embodiment, the interposer 10 has a relatively simple structure as compared to the conventional structures, so that it can be manufactured at a low cost.

### 3. Experiment Regarding Stress of Heat Dissipation Vias in Circuit Device Including Interposer According to Third Embodiment

Next, with reference to FIG. 6, an experimental example will be described that is an experiment regarding a relationship between the ratio of the inner diameter of the opening of the insulating layer to the outer diameter of the heat dissipation via (hereinafter referred to as the “opening diameter ratio”) and the ratio of the stress (hereinafter referred to as the “via stress”) generated in the heat dissipation via (hereinafter referred to as “via stress ratio”) in the circuit device including the interposer according to the third embodiment.

FIG. 6 shows a graph plotted using a function that gives the correlation between the ratio of the inner diameter of the opening of the insulating layer to the outer diameter of the heat dissipation via and the stress generated in the heat dissipation via in the circuit device including the interposer according to the first embodiment and the second embodiment.

As a result of examining the relationship between the opening diameter ratio and the via stress obtained in this experimental example, data indicating the correlation between the two was obtained. The graph as illustrated in FIG. 6, for example, was plotted from the data indicating this correlation. Here, the horizontal axis indicates the opening diameter ratio, and the vertical axis indicates the via stress ratio. The via stress ratio is defined using a reference in which the stress generated in the heat dissipation via is set to 1 for an opening diameter ratio of 1.

As can be seen from the graph in FIG. 6 indicating the results of this experiment,
Although it was difficult to obtain a clear correlation because of the small amount of data for an opening diameter ratio of 1 or less, it was observed that the via stress ratio tended to be reduced to some extent.
It was found that the via stress ratio linearly decreased with a gentle slope (θ) for an opening diameter ratio of 1 to about 2.5.
It was found that the via stress ratio was minimized for an opening diameter ratio of about 2.5. That is, it was also found that the via stress ratio linearly increased with a relatively large slope (θ′, where θ′ ≈ 2θ) and had a positive correlation for an opening diameter ratio of over about 2.5.

From the above experimental results, for example, it is found that the appropriate opening diameter ratio is up to about 3 because, for an opening diameter ratio of over at least about 3, the increase rate of the via stress ratio to the opening diameter ratio increases. This leads to a conclusion that the inner diameter of the opening of the insulating layer is preferably formed to be within three times the outer diameter of the heat dissipation via 15 from the fact that as already described with reference to FIG. 5, if the size of the opening 12B is excessively large compared to the outer diameter of the heat dissipation via 15, a difference in linear expansion coefficient between the resin with high thermal conductivity (Ag paste in the present embodiment) of the filling layer 19 formed by filling the opening 12B and the resin with low thermal conductivity (solder resist) serving as the insulating layer 12 may cause an increase in stress. In addition, for an opening diameter ratio of less than 1, such an opening is not preferable from the viewpoint of reduced heat dissipation efficiency.

Based on the above knowledge obtained from the experimental results, the first embodiment of the present technology is implemented in which the opening 12B having a circular shape and an opening diameter ratio is applied to the interposer 10. However, the configuration of the opening of the present technology is not particularly limited to that of the opening 12B of the first embodiment.

Finally, the description of each embodiment described above is an example of the present disclosure, and the present disclosure is not limited to the above-described embodiments. Accordingly, it is needless to say that various modifications can be made depending on design and the like without departing from the technical spirit according to the present disclosure in addition to the above-described embodiments. Additionally, the effects described in the present specification are merely exemplary and are not limited. Other effects may be obtained as well.

In addition, the figures in the above-described embodiments are schematic, and dimensional ratios and the like of respective parts are not necessarily consistent with actual ones. Also, the figures of course include parts where dimensional relationships and ratios differ from drawing to drawing.

The present technology can also be configured as follows.

An interposer including:
a wiring substrate that is formed of an insulating resin;
a wiring via that is provided for electrical connection between both surfaces of the wiring substrate;
a plurality of heat dissipation vias that are provided fitting in a region of a chip mounting section where a semiconductor chip is mounted on the wiring substrate; and
an insulating layer that covers a surface of the wiring substrate exclusive of an opening of the wiring via and openings of the heat dissipation vias with an insulating resin with low thermal conductivity.

The interposer according to (1), wherein the heat dissipation vias each have a circular opening with a same diameter and are arranged in a grid pattern at equal intervals.

The interposer according to (1) or (2), wherein
the insulating resin with low thermal conductivity is a solder resist, and
the resin with high thermal conductivity is Ag paste.

A circuit device including:
a wiring substrate that is formed of an insulating resin;
a wiring via that is provided for electrical connection between both surfaces of the wiring substrate;
a plurality of heat dissipation vias that are provided in a region of a chip mounting section where a semiconductor chip is mounted on the wiring substrate;
an insulating layer that covers a surface of the wiring substrate exclusive of an opening of the wiring via and openings of the heat dissipation vias with an insulating resin with low thermal conductivity; and
an adhesive layer that is formed of a resin with high thermal conductivity so that a back surface of the semiconductor chip is adhesively fixed to the chip mounting section, and thermally connects the semiconductor chip to the heat dissipation vias.

The circuit device according to (4), wherein the heat dissipation vias each have a circular shape with a same opening diameter and are arranged in a grid pattern at equal intervals.

The circuit device according to (4) or (5), wherein
the insulating resin with low thermal conductivity is a solder resist, and
the resin with high thermal conductivity is Ag paste.

A method of manufacturing an interposer, including the steps of:
forming, on a wiring substrate that is formed of an insulating resin, a wiring via for electrical connection between both surfaces of the wiring substrate and a plurality of heat dissipation vias that each have an opening in a region of a chip mounting section where the semiconductor chip is mounted; and
forming an insulating layer to cover a surface of the wiring substrate exclusive of an opening of the wiring via and the openings of the heat dissipation vias with an insulating resin with low thermal conductivity.

The method of manufacturing an interposer according to (7), wherein the step of forming the heat dissipation vias includes forming each of the heat dissipation vias into a circular shape with a same opening diameter, and forming the heat dissipation vias in a grid pattern at equal intervals.

The method of manufacturing an interposer according to (7) or (8), wherein
the step of forming the insulating layer includes forming the insulating layer by using a solder resist as the insulating resin with low thermal conductivity, and
the step of forming an adhesive layer includes using Ag paste as the resin with high thermal conductivity.

A method of manufacturing a circuit device including the steps of:
forming, on a wiring substrate that is formed of an insulating resin, a wiring via for electrical connection between both surfaces of the wiring substrate and a plurality of heat dissipation vias that each have an opening in a region of a chip mounting section where the semiconductor chip is mounted;
forming an insulating layer to cover a surface of the wiring substrate exclusive of an opening of the wiring via and the openings of the heat dissipation vias with an insulating resin with low thermal conductivity;
forming an adhesive layer for bonding and fixing a back surface of the semiconductor chip to the chip mounting section with a resin with high thermal conductivity to thermally connect the semiconductor chip and the heat dissipation vias; and bonding and fixing the semiconductor chip to the adhesive layer face-up.

The method of manufacturing a circuit device according to (10), wherein the step of forming the heat dissipation vias includes forming each of the heat dissipation vias into an opening circular shape with a same diameter, and forming the heat dissipation vias in a grid pattern at equal intervals.

The method of manufacturing a circuit device according to (10) or (11), wherein
the step of forming the insulating layer includes forming the insulating layer by using a solder resist as the insulating resin with low thermal conductivity, and
the step of forming an adhesive layer includes using Ag paste as the resin with high thermal conductivity.

A method of manufacturing a circuit device including the steps of:
forming, on a wiring substrate that is formed of an insulating resin, a wiring via for electrical connection between both surfaces of the wiring substrate and a plurality of heat dissipation vias that each have an opening in a region of a chip mounting section where the semiconductor chip is mounted;
forming an insulating layer to cover a surface of the wiring substrate exclusive of an opening of the wiring via and the openings of the heat dissipation vias with an insulating resin with low thermal conductivity;
coating a resin with high thermal conductivity on a back surface of the semiconductor chip; and
forming an adhesive layer by bonding and fixing the semiconductor chip with the resin with high thermal conductivity coated to the chip mounting section on the wiring substrate side face-up to thermally connect the semiconductor chip and the heat dissipation vias.

The method of manufacturing a circuit device according to (13), wherein the step of forming the heat dissipation vias includes forming each of the heat dissipation vias into an opening circular shape with a same diameter, and forming the heat dissipation vias in a grid pattern at equal intervals.

The method of manufacturing a circuit device according to (13) or (14), wherein the step of forming the insulating layer includes forming the insulating layer by using a solder resist as the insulating resin with low thermal conductivity, and the step of forming an adhesive layer includes using Ag paste as the resin with high thermal conductivity.

### REFERENCE SIGNS LIST

1 Circuit device
10 Interposer
11 Substrate (wiring substrate)
11A Top metal layer
11B Bottom metal layer
11C Hole (wiring via hole)
11D Hole (heat dissipation via hole)
12, 13 Insulating layer
12A Opening (for wiring via)
12B Opening (for heat dissipation via)
13A Opening (for wiring terminal)
13B Opening (for ground terminal)
14 Wiring via
14A Via hole (for wiring via)
15 Heat dissipation via
15A Via hole (for heat dissipation via)
15B Heat dissipation protrusion (heat dissipation via protruding portion)
16 Wiring terminal (conductive layer)
17 Ground terminal (conductive layer)
18 Pattern wire (conductive layer)
19 Filling portion (Ag paste)
20 Semiconductor chip
30 Mold resin portion
30′ Filling resin portion
40 Wire (Au wire)
50 Adhesive layer (Ag paste)
50′ Adhesive
MA Chip mounting section
SR Solder resist
TR Thermal route (heat conduction route)

1. An interposer comprising:
a wiring substrate that is formed of an insulating resin;
a wiring via that is provided for electrical connection between both surfaces of the wiring substrate;
a plurality of heat dissipation vias that are provided fitting in a region of a chip mounting section where a semiconductor chip is mounted on the wiring substrate; and
an insulating layer that covers a surface of the wiring substrate exclusive of an opening of the wiring via and openings of the heat dissipation vias with an insulating resin with low thermal conductivity.

2. The interposer according to claim 1, wherein the heat dissipation vias each have a circular opening with a same diameter and are arranged in a grid pattern at equal intervals.

3. The interposer according to claim 1, wherein
the insulating resin with low thermal conductivity is a solder resist, and
the resin with high thermal conductivity is Ag paste.

4. A circuit device comprising:
a wiring substrate that is formed of an insulating resin;
a wiring via that is provided for electrical connection between both surfaces of the wiring substrate;
a plurality of heat dissipation vias that are provided in a region of a chip mounting section where a semiconductor chip is mounted on the wiring substrate;
an insulating layer that covers a surface of the wiring substrate exclusive of an opening of the wiring via and openings of the heat dissipation vias with an insulating resin with low thermal conductivity; and
an adhesive layer that is formed of a resin with high thermal conductivity so that a back surface of the semiconductor chip is adhesively fixed to the chip mounting section, and thermally connects the semiconductor chip to the heat dissipation vias.

5. The circuit device according to claim 4, wherein the heat dissipation vias each have a circular shape with a same opening diameter and are arranged in a grid pattern at equal intervals.

6. The circuit device according to claim 4, wherein
the insulating resin with low thermal conductivity is a solder resist, and
the resin with high thermal conductivity is Ag paste.

7. A method of manufacturing an interposer, comprising the steps of:
forming, on a wiring substrate that is formed of an insulating resin, a wiring via for electrical connection between both surfaces of the wiring substrate and a plurality of heat dissipation vias that each have an opening in a region of a chip mounting section where the semiconductor chip is mounted; and
forming an insulating layer to cover a surface of the wiring substrate exclusive of an opening of the wiring via and the openings of the heat dissipation vias with an insulating resin with low thermal conductivity.

8. The method of manufacturing an interposer according to claim 7, wherein the step of forming the heat dissipation vias includes forming each of the heat dissipation vias into a circular shape with a same opening diameter, and forming the heat dissipation vias in a grid pattern at equal intervals.

9. The method of manufacturing an interposer according to claim 7, wherein
the step of forming the insulating layer includes forming the insulating layer by using a solder resist as the insulating resin with low thermal conductivity, and
the step of forming an adhesive layer includes using Ag paste as the resin with high thermal conductivity.

10. A method of manufacturing a circuit device, comprising the steps of:
forming, on a wiring substrate that is formed of an insulating resin, a wiring via for electrical connection between both surfaces of the wiring substrate and a plurality of heat dissipation vias that each have an opening in a region of a chip mounting section where the semiconductor chip is mounted;
forming an insulating layer to cover a surface of the wiring substrate exclusive of an opening of the wiring via and the openings of the heat dissipation vias with an insulating resin with low thermal conductivity;
forming an adhesive layer for bonding and fixing a back surface of the semiconductor chip to the chip mounting section with a resin with high thermal conductivity to thermally connect the semiconductor chip and the heat dissipation vias; and bonding and fixing the semiconductor chip to the adhesive layer face-up.

11. The method of manufacturing a circuit device according to claim 10, wherein the step of forming the heat dissipation vias includes forming each of the heat dissipation vias into an opening circular shape with a same diameter, and forming the heat dissipation vias in a grid pattern at equal intervals.

12. The method of manufacturing a circuit device according to claim 10, wherein
the step of forming the insulating layer includes forming the insulating layer by using a solder resist as the insulating resin with low thermal conductivity, and the step of forming an adhesive layer includes using Ag paste as the resin with high thermal conductivity.

13. A method of manufacturing a circuit device, comprising the steps of:
forming, on a wiring substrate that is formed of an insulating resin, a wiring via for electrical connection between both surfaces of the wiring substrate and a plurality of heat dissipation vias that each have an opening in a region of a chip mounting section where the semiconductor chip is mounted;
forming an insulating layer to cover a surface of the wiring substrate exclusive of an opening of the wiring via and the openings of the heat dissipation vias with an insulating resin with low thermal conductivity;
coating a resin with high thermal conductivity on a back surface of the semiconductor chip; and
forming an adhesive layer by bonding and fixing the semiconductor chip with the resin with high thermal conductivity coated to the chip mounting section on the wiring substrate side face-up to thermally connect the semiconductor chip and the heat dissipation vias.

14. The method of manufacturing a circuit device according to claim 13, wherein the step of forming the heat dissipation vias includes forming each of the heat dissipation vias into an opening circular shape with a same diameter, and forming the heat dissipation vias in a grid pattern at equal intervals.

15. The method of manufacturing a circuit device according to claim 13, wherein the step of forming the insulating layer includes forming the insulating layer by using a solder resist as the insulating resin with low thermal conductivity, and the step of forming an adhesive layer includes using Ag paste as the resin with high thermal conductivity.
